(19) United States
(12) Patent Application Publication
(10) Pub. No.: US 2026/0156755 A1
(43) Pub. Date: Jun. 4, 2026

(54) MULTILAYER SUBSTRATE MODULE AND ELECTRONIC DEVICE

(71) Applicant: Murata Manufacturing Co., Ltd., Nagaokakyo-shi (JP)

(72) Inventors: Noriaki OKUDA, Nagaokakyo-shi (JP); Akihiro YAMAKAWA, Nagaokakyo-shi (JP); Toru YOSHIOKA, Nagaokakyo-shi (JP); Shunta FURUZAWA, Nagaokakyo-shi (JP)

(73) Assignee: Murata Manufacturing Co., Ltd., Nagaokakyo-shi (JP)

(21) Appl. No.: 19/457,181

(22) Filed: Jan. 23, 2026

Related U.S. Application Data
(63) Continuation of application No. PCT/JP2024/022984, filed on Jun. 25, 2024.

(30) Foreign Application Priority Data
Jul. 26, 2023 (JP) 2023-122017

(51) Int. Cl. H05K 1/189; H05K 1/02

(52) U.S. Cl. CPC H05K 1/189; H05K 1/0298; H05K 2201/10098

(57) ABSTRACT

A multilayer substrate module includes a rigid section in which a first multilayer substrate, a dielectric component, and a second multilayer substrate are laminated, and a flexible section in which the first multilayer substrate and the second multilayer substrate are laminated without the dielectric component interposed therebetween. The rigid section includes a radiating electrode and a ground electrode. At least one selected from a plurality of first conductive layers and a second conductive layer includes a conductor portion included in the flexible section and the rigid section. The flexible section has a thickness less than a thickness of the rigid section.

### CROSS-REFERENCE TO RELATED APPLICATIONS

This application is a continuation of International Application No. PCT/JP 2024/022984, filed Jun. 25, 2024, which claims priority to Japanese Patent Application No. 2023-122017, filed Jul. 26, 2023, the entire contents of each of which are hereby incorporated by reference.

### TECHNICAL FIELD

The present disclosure generally relates to multilayer substrate modules and electronic devices, and more particularly, to a multilayer substrate module including a radiating electrode and an electronic device including the multilayer substrate module.

### BACKGROUND ART

Patent Document 1 describes a millimeter-wave module (multilayer substrate module) including an insulating substrate, a dielectric block (dielectric component), and an antenna.

The insulating substrate has a first principal surface and a second principal surface that are parallel to each other and disposed at different positions in a thickness direction. The dielectric block is disposed in the insulating substrate. The dielectric block is disposed between the first principal surface and the second principal surface of the insulating substrate. The dielectric block has a dielectric constant that differs from the dielectric constant of the insulating substrate.

### CITATION LIST

### Patent Document

Patent Document 1: International Publication No. 2019/207828

### SUMMARY

### Technical Problems

The millimeter-wave module (multilayer substrate module) described in Patent Document 1 includes the dielectric block (dielectric component) disposed in the insulating substrate, causing the thickness and weight of the insulating substrate to increase.

The present disclosure is directed to providing a multilayer substrate module and an electronic device that can be reduced in weight.

### Solutions to Problems

A multilayer substrate module according to an aspect of the present disclosure includes a first multilayer substrate, a second multilayer substrate, and a dielectric component. The first multilayer substrate includes a plurality of first insulating layers and a plurality of first conductive layers. The plurality of first insulating layers and the plurality of first conductive layers are laminated. The second multilayer substrate includes a second insulating layer and a second conductive layer. The second insulating layer and the second conductive layer are laminated. The dielectric component is disposed between the first multilayer substrate and the second multilayer substrate. In the multilayer substrate module, a section in which the first multilayer substrate, the dielectric component, and the second multilayer substrate are laminated is defined as a rigid section, and a section in which the first multilayer substrate and the second multilayer substrate are laminated without the dielectric component interposed therebetween is defined as a flexible section. The rigid section includes a radiating electrode and a ground electrode. The radiating electrode includes a portion of one conductive layer selected from the plurality of first conductive layers and the second conductive layer in a thickness direction of the rigid section. The radiating electrode overlaps the dielectric component in the thickness direction. The ground electrode includes a portion of one of the plurality of first conductive layers and faces the radiating electrode in the thickness direction. At least one selected from the plurality of first conductive layers and the second conductive layer includes a conductor portion included in the flexible section and in the rigid section. The flexible section has a thickness less than a thickness of the rigid section.

An electronic device according to an aspect of the present disclosure includes the multilayer substrate module according to the above-described aspect and a housing. The housing accommodates the multilayer substrate module.

### Advantageous Effects

The multilayer substrate module and the electronic device according to the above-described aspects of the present disclosure can be reduced in weight.

### BRIEF DESCRIPTION OF DRAWINGS

FIG. 1 is a sectional view of a main part of a multilayer substrate module according to a first embodiment.

FIG. 2 is a sectional view of the multilayer substrate module.

FIG. 3 is a sectional view of the multilayer substrate module taken along line III-III in FIG. 1.

FIG. 4 is an exploded perspective view of the multilayer substrate module.

FIG. 5 is a partially broken, exploded perspective view of the multilayer substrate module.

FIG. 6 illustrates a method for manufacturing the multilayer substrate module.

FIG. 7 is a sectional view of a main part of an electronic device including the multilayer substrate module.

FIG. 8 is a sectional view of a multilayer substrate module according to a second embodiment.

FIG. 9 is another sectional view of the multilayer substrate module.

FIG. 10 illustrates a method for manufacturing the multilayer substrate module.

FIG. 11 is a sectional view of a multilayer substrate module according to a third embodiment.

FIG. 12 is a sectional view of a main part of a multilayer substrate module according to a fourth embodiment.

FIG. 13 is a sectional view of the multilayer substrate module taken along line XIII-XIII in FIG. 12.

FIG. 14 illustrates a method for manufacturing the multilayer substrate module.

FIG. 15 is an exploded perspective view of the multilayer substrate module.

FIG. 16 is a sectional view of a multilayer substrate module according to a fifth embodiment.

FIG. 17 is a partially broken plan view of another example of an electronic device including the multilayer substrate module according to the first embodiment.

FIG. 18 is a sectional view of the electronic device taken along line XVIII-XVIII in FIG. 17.

FIG. 19 is a sectional view of a main part of another example of an electronic device including the multilayer substrate module according to the first embodiment.

### DESCRIPTION OF EMBODIMENTS

First to fifth and other embodiments will be described with reference to the drawings. The drawings referred to below in the first to fifth and other embodiments are schematic. The sizes and thicknesses of the components in the drawings do not necessarily reflect actual dimensions, and the size ratios and thickness ratios between the components also do not necessarily reflect the actual dimensional ratios.

### First Embodiment

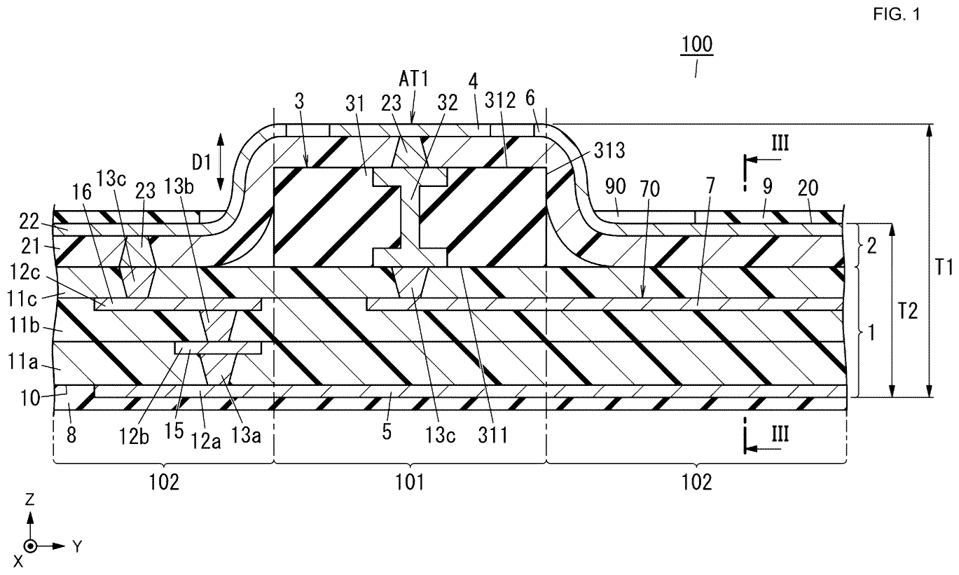

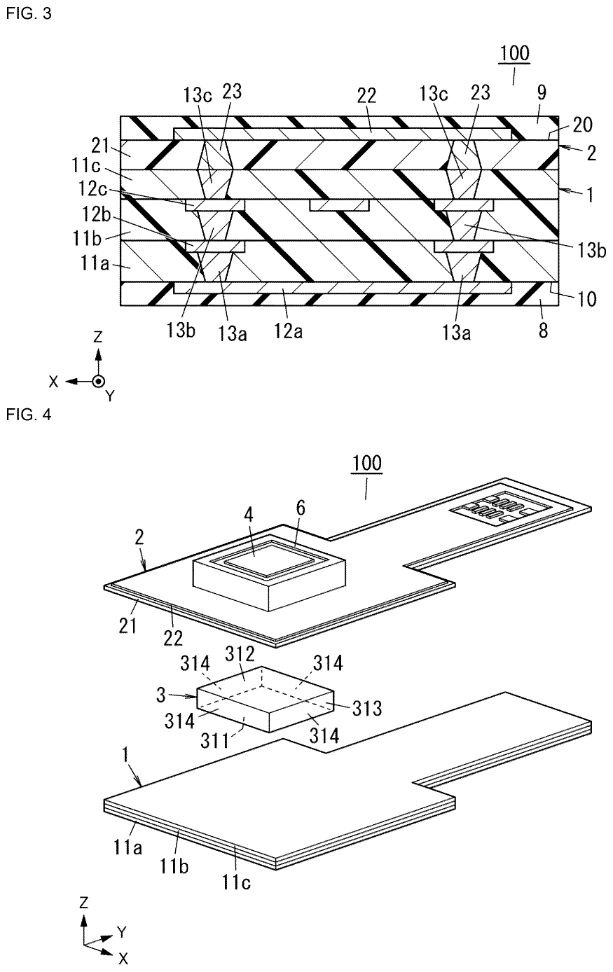

A multilayer substrate module and an electronic device according to a first embodiment will be described with reference to FIGS. 1 to 7.

### (1) Multilayer Substrate Module

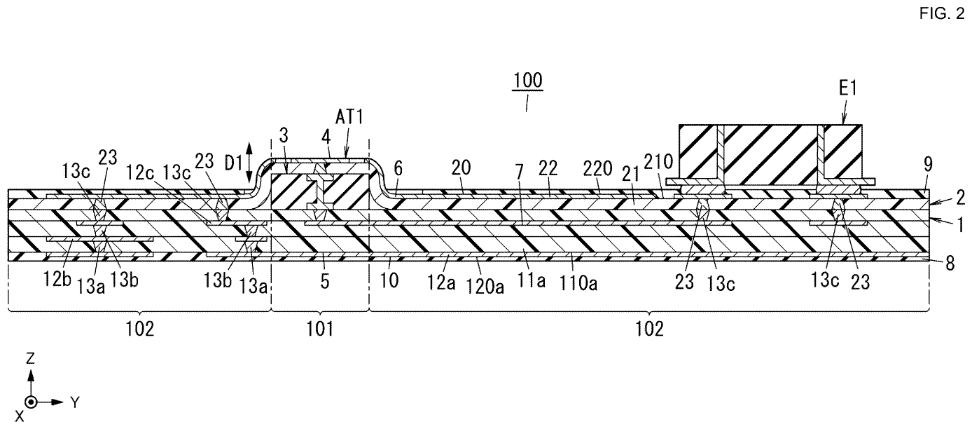

As illustrated in FIGS. 1 and 2, a multilayer substrate module 100 according to the first embodiment includes a first multilayer substrate 1, a second multilayer substrate 2, and a dielectric component 3. In the multilayer substrate module 100, a section in which the first multilayer substrate 1, the dielectric component 3, and the second multilayer substrate 2 are laminated is defined as a rigid section 101, and a section in which the first multilayer substrate 1 and the second multilayer substrate 2 are laminated without the dielectric component 3 interposed therebetween is defined as a flexible section 102. The rigid section 101 includes a radiating electrode 4. In each of FIGS. 1 to 7, an orthogonal coordinate system having three axes, an X-axis, a Y-axis, and a Z-axis that are orthogonal to each other, is defined, and the axis along a thickness direction D1 of the rigid section 101 (see FIG. 1) is designated as the Z-axis. The X-axis, the Y-axis, and the Z-axis are all imaginary axes, and the arrows denoted by “X”, “Y”, and “Z” are merely for description and involve no actual substance.

The multilayer substrate module 100 according to the first embodiment further includes a first cover layer 8 and a second cover layer 9. The multilayer substrate module 100 according to the first embodiment further includes an electronic component E1.

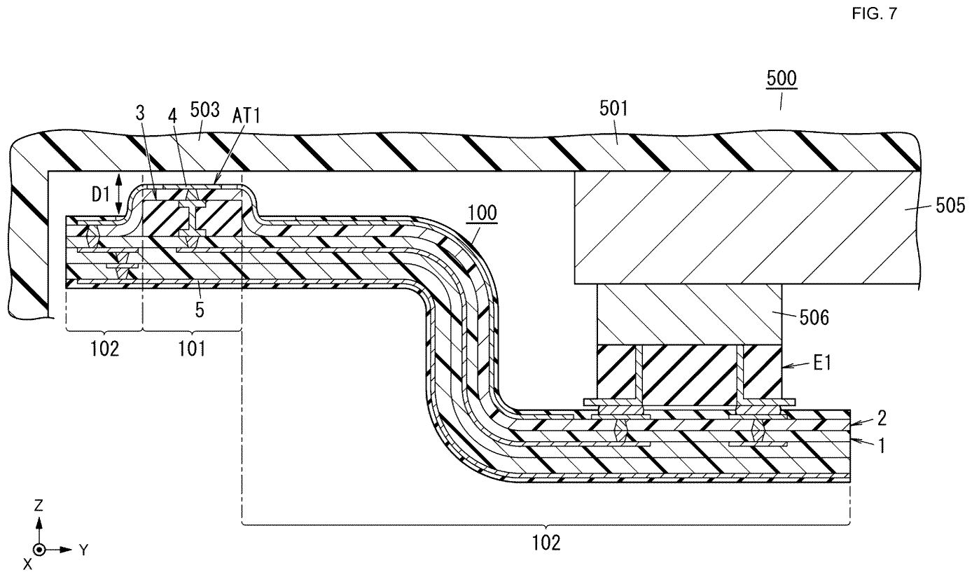

As illustrated in FIG. 7, the multilayer substrate module 100 is, for example, accommodated in a housing 501 of an electronic device 500. The electronic device 500 is, for example, a communication device. The communication device is, for example, a cellular phone (for example, a smartphone), but is not limited to a cellular phone. For example, the communication device may be a notebook personal computer, a wearable terminal (for example, a smartwatch), or the like.

### (1.1) First Multilayer Substrate

As illustrated in FIGS. 1 to 3, the first multilayer substrate 1 includes a plurality of first insulating layers 11a, 11b, and 11c (three first insulating layers in FIG. 1) and a plurality of first conductive layers 12a, 12b, and 12c (three first conductive layers in FIG. 1). The first insulating layers 11a, 11b, and 11c and the first conductive layers 12a, 12b, and 12c are laminated. The first multilayer substrate 1 has a principal surface 10 on a side opposite to the side adjacent to the second multilayer substrate 2. The first multilayer substrate 1 further includes a plurality of first interlayer connection conductors 13a, a plurality of first interlayer connection conductors 13b, and a plurality of first interlayer connection conductors 13c.

The material of each of the first insulating layers 11a, 11b, and 11c includes, for example, a thermoplastic resin. The thermoplastic resin is, for example, a liquid crystal polymer. The thermoplastic resin is not limited to a liquid crystal polymer and may be, for example, polytetrafluoroethylene (PTFE).

Each of the first insulating layers 11a, 11b, and 11c has a thickness of, for example, 10μm or more and 120μm or less.

Each of the first conductive layers 12a, 12b, and 12c is conductive. The material of each of the first conductive layers 12a, 12b, and 12c includes, for example, copper.

Each of the first conductive layers 12a, 12b, and 12c has a thickness of, for example, 3 μm or more and 40 μm or less.

The first conductive layers 12a, 12b, and 12c are formed in predetermined patterns determined for each layer. The first conductive layer 12a is formed by, for example, patterning a copper foil attached to the first insulating layer 11a. The first conductive layer 12b is formed by, for example, patterning a copper foil attached to the first insulating layer 11b. The first conductive layer 12c is formed by patterning a copper foil attached to the first insulating layer 11c. Each of the first conductive layers 12a, 12b, and 12c includes a plurality of conductor portions.

In the present embodiment, of the first conductive layers 12a, 12b, and 12c, the first conductive layer 12a that is farthest from the dielectric component 3 includes a ground electrode 5 (hereinafter also referred to as a first ground electrode 5). More specifically, one of the conductor portions included in the first conductive layer 12a constitutes the first ground electrode 5. In the present embodiment, the first ground electrode 5 is included in the rigid section 101 and in the flexible section 102. In a plan view as viewed in the thickness direction D1 of the rigid section 101, the first ground electrode 5 overlaps the radiating electrode 4. The first ground electrode 5 faces the radiating electrode 4 in the thickness direction D1 of the rigid section 101. The first ground electrode 5 faces a signal line 7 connected to the radiating electrode 4. The first ground electrode 5 overlaps the signal line 7 in a thickness direction of the multilayer substrate module 100. The multilayer substrate module 100 includes a strip line 70 including the signal line 7, the first ground electrode 5, and a second ground electrode 6. When the flexible section 102 of the multilayer substrate module 100 is bent as illustrated in FIG. 7, the thickness direction of the multilayer substrate module 100 varies depending on the position along the flexible section 102.

In the present embodiment, as illustrated in FIG. 1, the conductor portions included in the first conductive layer 12b, which is one of the first conductive layers 12a, 12b, and 12c that is second farthest from the dielectric component 3, include a ground conductor portion 15. The ground conductor portion 15 is connected to the first ground electrode 5 through one of the first interlayer connection conductors 13a.

In the present embodiment, of the first conductive layers 12a, 12b, and 12c, the first conductive layer 12c that is closest to the dielectric component 3 includes a signal line 7. More specifically, one of the conductor portions included in the first conductive layer 12c constitutes the signal line 7. In the present embodiment, the signal line 7 is included in the rigid section 101 and in the flexible section 102.

The conductor portions included in the first conductive layer 12c also include a ground conductor portion 16 that is connected to the first ground electrode 5 through one of the first interlayer connection conductors 13b and the like.

Each of the first interlayer connection conductors 13a, the first interlayer connection conductors 13b, and the first interlayer connection conductors 13c is conductive. Each of the first interlayer connection conductors 13a, the first interlayer connection conductors 13b, and the first interlayer connection conductors 13c contains, for example, copper, a copper-tin alloy, and a resin. The first interlayer connection conductors 13a are formed by, for example, filling a plurality of via holes formed in the first insulating layer 11a with conductive paste containing copper, a low-melting-point metal (for example, tin), and a resin while each via hole is blocked by a portion of a copper foil, and applying heat. The first interlayer connection conductors 13b are formed by, for example, filling a plurality of via holes formed in the first insulating layer 11b with conductive paste containing copper, a low-melting-point metal (for example, tin), and a resin while each via hole is blocked by a portion of a copper foil, and applying heat. The first interlayer connection conductors 13c are formed by, for example, filling a plurality of via holes formed in the first insulating layer 11c with conductive paste containing copper, a low-melting-point metal (for example, tin), and a resin while each via hole is blocked by a portion of a copper foil, and applying heat.

### (1.2) Second Multilayer Substrate

The second multilayer substrate 2 is laminated onto the first multilayer substrate 1. More specifically, the second multilayer substrate 2 is laminated onto the first multilayer substrate 1 so as to cover the dielectric component 3 on the first multilayer substrate 1. The second multilayer substrate 2 has a principal surface 20 on a side opposite to the side adjacent to the first multilayer substrate 1.

The second multilayer substrate 2 includes a second insulating layer 21 and a second conductive layer 22. The second insulating layer 21 and the second conductive layer 22 are laminated. The second multilayer substrate 2 further includes a plurality of second interlayer connection conductors 23. In the present embodiment, the second insulating layer 21 is bonded to the first insulating layer 11c. More specifically, in the present embodiment, the second insulating layer 21 and the first insulating layer 11c are self-bonded, and no adhesive layer is interposed between the second insulating layer 21 and the first insulating layer 11c.

The material of the second insulating layer 21 includes, for example, a thermoplastic resin. The thermoplastic resin is, for example, a liquid crystal polymer. The thermoplastic resin is not limited to a liquid crystal polymer, and may be, for example, PTFE. In the present embodiment, the material of the second insulating layer 21 and the material of each of the first insulating layers 11a, 11b, and 11c include the same material as the main constituent material thereof. The main constituent material means the main component.

The second insulating layer 21 has a thickness of, for example, 10 μm or more and 120 μm or less.

The second conductive layer 22 is conductive. The material of the second conductive layer 22 includes, for example, copper.

The second conductive layer 22 has a thickness of, for example, 3 μm or more and 40 μm or less.

The second conductive layer 22 is formed in a predetermined pattern. The second conductive layer 22 includes a plurality of conductor portions. The second conductive layer 22 is formed by, for example, patterning a copper foil attached to the second insulating layer 21.

In the present embodiment, the second conductive layer 22 includes the radiating electrode 4. More specifically, one of the conductor portions included in the second conductive layer 22 constitutes the radiating electrode 4. In the present embodiment, the radiating electrode 4 is included in the rigid section 101.

In a plan view as viewed in the thickness direction D1 of the rigid section 101, the radiating electrode 4 has, for example, a square shape. However, the shape of the radiating electrode 4 is not limited to a square shape and may be, for example, a rectangular shape.

The radiating electrode 4 overlaps the dielectric component 3 in the thickness direction D1 of the rigid section 101. More specifically, in the present embodiment, the entire radiating electrode 4 overlaps the dielectric component 3 in the thickness direction D1 of the rigid section 101. In the multilayer substrate module 100 of the present embodiment, the radiating electrode 4, a portion of the first ground electrode 5 that overlaps the radiating electrode 4 in the thickness direction D1 of the rigid section 101, and a portion of the rigid section 101 disposed between the radiating electrode 4 and the first ground electrode 5 in the thickness direction D1 of the rigid section 101 constitute an antenna (patch antenna) AT1. The antenna characteristics of the antenna AT1 are affected by the capacitance between the radiating electrode 4 and the first ground electrode 5. Therefore, in the present embodiment, the radiating electrode 4 and the first ground electrode 5 are spaced apart from each other in the thickness direction D1 of the rigid section 101 to reduce the capacitance.

In the present embodiment, the second conductive layer 22 also includes the ground electrode 6 (hereinafter also referred to as a second ground electrode 6) different from the first ground electrode 5. More specifically, one of the conductor portions included in the second conductive layer 22 constitutes the second ground electrode 6. The second ground electrode 6 is included in the rigid section 101 and in the flexible section 102. In the present embodiment, the second ground electrode 6 is laminated on the second insulating layer 21 so as to extend over a portion of the second insulating layer 21 included in the rigid section 101 and a portion of the second insulating layer 21 included in the flexible section 102.

In the present embodiment, the second ground electrode 6 surrounds the radiating electrode 4 in a plan view as viewed in the thickness direction D1 of the rigid section 101 (see FIG. 4). The second ground electrode 6 and the radiating electrode 4 are spaced apart from each other.

Each of the second interlayer connection conductors 23 is conductive. Each of the second interlayer connection conductors 23 contains, for example, copper, a copper-tin alloy, and a resin. The second interlayer connection conductors 23 are formed by, for example, filling a plurality of via holes formed in the second insulating layer 21 with conductive paste containing copper, a low-melting-point metal (for example, tin), and a resin while each via hole is blocked by a portion of a copper foil, and applying heat.

One of the second interlayer connection conductors 23 is connected to the radiating electrode 4. The second interlayer connection conductor 23 connected to the radiating electrode 4 serves as a feed point of the antenna AT1. Another one of the second interlayer connection conductors 23 is connected to the second ground electrode 6 and the first ground electrode 5 of the first multilayer substrate 1.

### (1.3) Dielectric Component

The dielectric component 3 is disposed between the first multilayer substrate 1 and the second multilayer substrate 2.

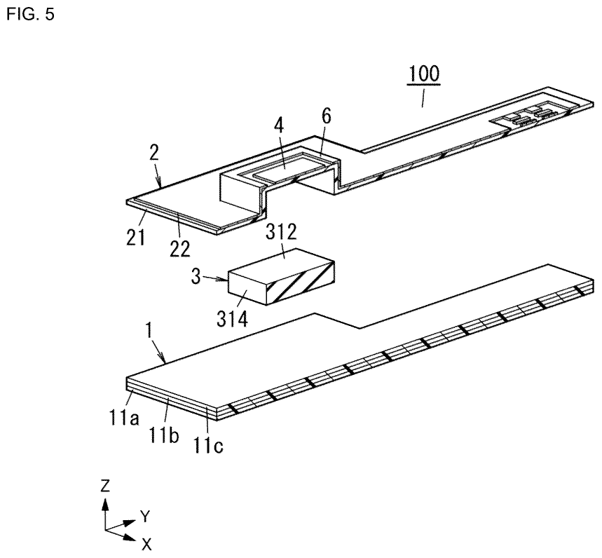

In the present embodiment, the dielectric component 3 is covered by the first multilayer substrate 1 and the second multilayer substrate 2. More specifically, in the present embodiment, the dielectric component 3 is disposed on the first multilayer substrate 1 and sealed with the second multilayer substrate 2. The dielectric component 3 has a first principal surface 311 adjacent to the first multilayer substrate 1, a second principal surface 312 on a side opposite to the side of the first principal surface 311, and an outer peripheral surface 313 connecting the first principal surface 311 and the second principal surface 312. In the present embodiment, the outer peripheral surface 313 includes four side surfaces 314 (see FIGS. 4 and 5). In the dielectric component 3, the first principal surface 311 is covered by the first multilayer substrate 1, and the second principal surface 312 and the outer peripheral surface 313 are covered by the second multilayer substrate 2.

The thickness of the dielectric component 3 in the thickness direction D1 of the rigid section 101 is greater than the thickness of the second multilayer substrate 2. In the present embodiment, the thickness of the second multilayer substrate 2 is the sum of the thickness of the second insulating layer 21 and the thickness of the second conductive layer 22.

In the present embodiment, the dielectric component 3 includes a dielectric substrate 31 and a through-electrode 32 extending through the dielectric substrate 31. The through-electrode 32 connects the second interlayer connection conductor 23 connected to the radiating electrode 4 in the second multilayer substrate 2 and the first interlayer connection conductor 13c connected to the signal line 7 in the first multilayer substrate 1.

In the present embodiment, the material of the dielectric substrate 31 includes a ceramic. That is, in the present embodiment, the dielectric material of the dielectric component 3 includes a ceramic. The ceramic is, for example, a low temperature co-fired ceramic (LTCC). The ceramic is not limited to an LTCC, and may be, for example, a high temperature co-fired ceramic (HTCC). The dielectric material of the dielectric component 3 is not limited to a ceramic, and may be, for example, an FR-4 (Flame Retardant Type 4) grade glass epoxy resin. In this case, the dielectric component 3 includes, for example, an FR-4 grade glass epoxy resin substrate. The material of the through-electrode 32 includes, for example, copper.

In the present embodiment, the relative dielectric constant of the dielectric material of the dielectric component 3 is greater than the relative dielectric constant of the material of each of the first insulating layers 11a, 11b, and 11c. The relative dielectric constant of the dielectric material of the dielectric component 3 is also greater than the relative dielectric constant of the material of the second insulating layer 21. For example, the relative dielectric constant of the LTCC is 6.5 in a frequency range of, for example, 1 GHz to 25 GHz, and the relative dielectric constant of the liquid crystal polymer is 2.8 in a frequency range of, for example, 1 GHz to 25 GHz.

In the present embodiment, the Young's modulus of the dielectric material of the dielectric component 3 is greater than the Young's modulus of the material of each of the first insulating layers 11a, 11b, and 11c. The Young's modulus of the dielectric material of the dielectric component 3 is also greater than the Young's modulus of the material of the second insulating layer 21. For example, the Young's modulus of the LTCC is 100 GPa, and the Young's modulus of the liquid crystal polymer is 5 GPa.

### (1.4) First Cover Layer

The first cover layer 8 covers the principal surface 10 of the first multilayer substrate 1 on a side opposite to the side adjacent to the second multilayer substrate 2.

The first cover layer 8 includes, for example, a polyimide film and an adhesive layer. The material of the adhesive layer includes, for example, an acrylic resin, a silicone resin, an epoxy resin, or a urethane resin.

### (1.5) Second Cover Layer

The second cover layer 9 is provided on the principal surface 20 of the second multilayer substrate 2 on a side opposite to the side adjacent to the first multilayer substrate 1. The principal surface 20 of the second multilayer substrate 2 includes a principal surface 220 (see FIG. 2) of the second conductive layer 22 and a portion of a principal surface 210 (see FIG. 2) of the second insulating layer 21 that is not covered with the second conductive layer 22. The second cover layer 9 has an opening 90 at which the rigid section 101 is exposed in the thickness direction D1 of the rigid section 101. Accordingly, the second cover layer 9 does not cover the radiating electrode 4.

The second cover layer 9 includes, for example, a polyimide film and an adhesive layer. The material of the adhesive layer includes, for example, an acrylic resin, a silicone resin, an epoxy resin, or a urethane resin.

### (1.6) Electronic Component

As illustrated in FIG. 2, the electronic component E1 is disposed in the flexible section 102. More specifically, the electronic component E1 is disposed on the principal surface 20 of the second multilayer substrate 2 in the flexible section 102. The expression “the electronic component E1 is disposed in the flexible section 102” includes both a state in which the electronic component E1 is mechanically connected to the flexible section 102 and a state in which the electronic component E1 is electrically connected to the flexible section 102.

The electronic component E1 is, for example, a connector. The electronic component E1 is not limited to a connector, and may be another electronic component, such as an IC chip or a surface-mounted electronic component (for example, a chip inductor or a chip capacitor).

### (2) Thickness of Multilayer Substrate Module

As illustrated in FIG. 1, in the multilayer substrate module 100, a thickness T1 of the rigid section 101 and a thickness T2 of the flexible section 102 are different. The “thickness T2 of the flexible section 102” is the thickness of a portion of the flexible section 102 in which the second multilayer substrate 2 and the first multilayer substrate 1 are parallel, and is not the thickness of a portion in which the second multilayer substrate 2 is at an angle relative to the first multilayer substrate 1 in a region near the boundary between the flexible section 102 and the rigid section 101. In the multilayer substrate module 100, the thickness T2 of the flexible section 102 is less than the thickness T1 of the rigid section 101.

### (3) Method for Manufacturing Multilayer Substrate Module

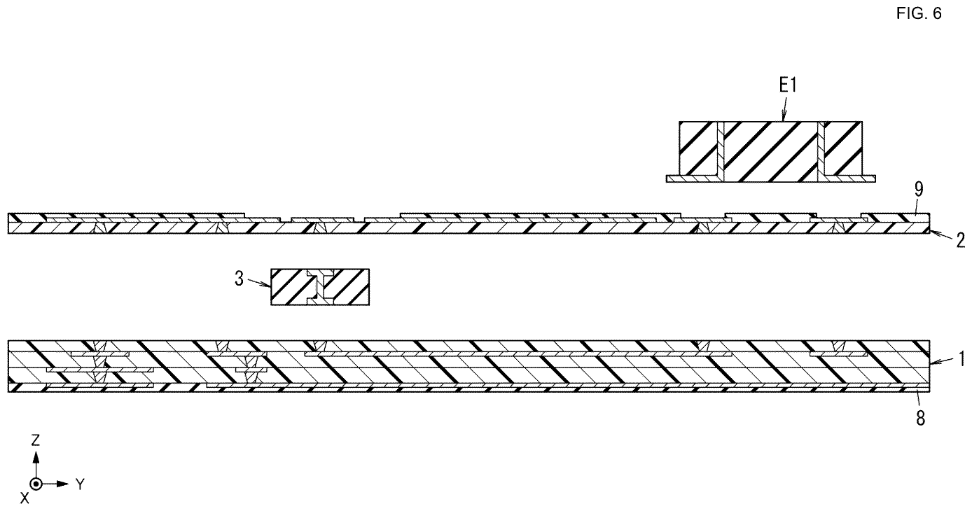

In the method for manufacturing the multilayer substrate module 100 according to the present embodiment, for example, as illustrated in FIG. 6, the first multilayer substrate 1, the dielectric component 3, and the second multilayer substrate 2 are prepared. For example, the first multilayer substrate 1 is placed on a metal plate, and the dielectric component 3 is placed on the first multilayer substrate 1. After that, the second multilayer substrate 2 is placed so as to cover the first multilayer substrate 1 and the dielectric component 3, and pressure is applied from above while heat is applied, thereby causing the first multilayer substrate 1 and the second multilayer substrate 2 to self-bond. Thus, the rigid section 101 (see FIG. 2) and the flexible section 102 (see FIG. 2) are formed. After that, the electronic component E1 is mounted on the flexible section 102 to obtain the multilayer substrate module 100 (see FIG. 2).

### (4) Electronic Device

As illustrated in FIG. 7, the electronic device 500 according to the first embodiment includes the multilayer substrate module 100 and the housing 501 that accommodates the multilayer substrate module 100. The electronic device 500 further includes a printed wiring board 505 and a connector 506.

The housing 501 includes a radio-wave transmissive portion 503 that allows radio waves emitted from the radiating electrode 4 of the multilayer substrate module 100 to pass therethrough. The radio-wave transmissive portion 503 is a resin portion that overlaps the radiating electrode 4 in the thickness direction of the rigid section 101, but is not limited to a resin portion and may be, for example, an opening.

In the electronic device 500, the connector 506 is disposed on the printed wiring board 505 accommodated in the housing 501. As illustrated in FIG. 7, the flexible section 102 of the multilayer substrate module 100 is bent by plastically deforming the thermoplastic resin, and the multilayer substrate module 100 maintains the shape thereof by itself. The connector 506 is removably attached and connected to the electronic component E1 of the multilayer substrate module 100. The printed wiring board 505 is, for example, a motherboard. A signal-processing circuit for processing high frequency signals, for example, is disposed on the printed wiring board 505. The term ‘circuitry’ or ‘signal-processing circuit’ as used herein may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable hardware components that provide the described functionality.

### (5) Effects

In the multilayer substrate module 100 according to the first embodiment, the section in which the first multilayer substrate 1, the dielectric component 3, and the second multilayer substrate 2 are laminated is defined as the rigid section 101, and the section in which the first multilayer substrate 1 and the second multilayer substrate 2 are laminated without the dielectric component 3 interposed therebetween is defined as the flexible section 102. The rigid section 101 includes the radiating electrode 4 and the ground electrode 5. The radiating electrode 4 includes a portion of one conductive layer (second conductive layer 22) selected from the first conductive layers 12a, 12b, and 12c and the second conductive layer 22 in the thickness direction D1 of the rigid section 101, and overlaps the dielectric component 3 in the thickness direction D1. The ground electrode 5 includes a portion of one of the first conductive layers 12a, 12b, and 12c (first conductive layer 12a), and faces the radiating electrode 4 in the thickness direction D1. At least one selected from the first conductive layers 12a, 12b, and 12c and the second conductive layer 22 (first conductive layer 12c) includes a conductor portion (signal line 7) included in the flexible section 102 and the rigid section 101. The flexible section 102 has the thickness T2 less than the thickness T1 of the rigid section 101.

According to the above-described configuration, the weight of the multilayer substrate module 100 can be reduced. More specifically, in the multilayer substrate module 100 according to the first embodiment, the rigid section 101 includes the radiating electrode 4 and the ground electrode 5, and the thickness T2 of the flexible section 102 is less than the thickness T1 of the rigid section 101. Therefore, the weight of the multilayer substrate module 100 can be reduced without degrading the antenna performance (performance of the antenna AT1 including the radiating electrode 4 and the ground electrode 5).

In the multilayer substrate module 100 according to the first embodiment, the relative dielectric constant of the dielectric material of the dielectric component 3 is greater than the relative dielectric constant of the material of each of the first insulating layers 11a, 11b, and 11c, and the relative dielectric constant of the dielectric material of the dielectric component 3 is also greater than the relative dielectric constant of the material of the second insulating layer 21.

According to the above-described structure, the size of the antenna AT1 including the radiating electrode 4 and the ground electrode 5 can be reduced.

In addition, in the multilayer substrate module 100 according to the first embodiment, the conductor portions included in the second conductive layer 22 include the second ground electrode 6 different from the first ground electrode 5 that is the ground electrode 5. The second ground electrode 6 is included in the rigid section 101 and in the flexible section 102.

According to the above-described structure, compared to when the second ground electrode 6 is divided into a portion included in the rigid section 101 and a portion included in the flexible section 102 that are connected to each other through an interlayer connection conductor, the potential of the second ground electrode 6 can be further stabilized, and noise resistance can be increased.

In the multilayer substrate module 100 according to the first embodiment, the second ground electrode 6 surrounds the radiating electrode 4 in a plan view of the rigid section 101 as viewed in the thickness direction D1.

According to this structure, noise resistance can be increased, and the directivity of the antenna AT1 including the radiating electrode 4 and the ground electrode 5 can also be increased.

In the multilayer substrate module 100 according to the first embodiment, of the first conductive layers 12a, 12b, and 12c, the first conductive layer 12c that is closest to the dielectric component 3 includes the signal line 7 included in the rigid section 101 and in the flexible section 102. In the multilayer substrate module 100, the first ground electrode 5 is included in the rigid section 101 and in the flexible section 102. The first ground electrode 5 faces the signal line 7. The second ground electrode 6 of the second conductive layer 22 is also included in the rigid section 101 and in the flexible section 102. The second ground electrode 6 faces the signal line 7 such that the second insulating layer 21 and the first insulating layer 11c, which is one of the first insulating layers 11a, 11b, and 11c that is closest to the dielectric component 3, are disposed between the second ground electrode 6 and the signal line 7.

According to this structure, in the multilayer substrate module 100, the distance between the signal line 7 and the first ground electrode 5 can be increased to reduce the capacitance between the signal line 7 and the first ground electrode 5, and the distance between the signal line 7 and the second ground electrode 6 can be increased to reduce the capacitance between the signal line 7 and the second ground electrode 6. As a result, in the multilayer substrate module 100, the line width of the signal line 7 can be increased, so that the resistance of the signal line 7 can be reduced, thereby reducing loss in the signal line 7. In addition, according to the above-described structure, since the capacitance between the signal line 7 and the first ground electrode 5 and the capacitance between the signal line 7 and the second ground electrode 6 can be reduced, the areas of the first ground electrode 5 and the second ground electrode 6 can be increased, so that the ground potential can be further stabilized.

Since the electronic device 500 according to the first embodiment includes the multilayer substrate module 100 and the housing 501, the weight of the multilayer substrate module 100 can be reduced.

### Modification of First Embodiment

For example, the second multilayer substrate 2 is not limited to a substrate having a structure including one second insulating layer 21 and one second conductive layer 22, and may have a structure including a plurality of second insulating layers 21 and a plurality of second conductive layers 22. In this case, the second multilayer substrate 2 may be formed by laminating the second insulating layers 21 and the second conductive layers 22.

In addition, the material of each of the first insulating layers 11a, 11b, and 11c may be polyimide. In this case, each of the first interlayer connection conductors 13a, the first interlayer connection conductors 13b, and the first interlayer connection conductors 13c may be formed of a plated through hole. The first interlayer connection conductors 13a, 13b, and 13c that are connected to each other in the first multilayer substrate 1 may be formed of a single plated through hole. In this case, the material of the plated through hole may be, for example, copper.

In the multilayer substrate module 100, each of the first cover layer 8 and the second cover layer 9 is not limited to a layer having a structure including a polyimide film and an adhesive layer, and may be, for example, a resist layer. The resist layer may be formed by, for example, spin-coating or photolithography.

In the multilayer substrate module 100, the entire radiating electrode 4 overlaps a portion of the dielectric component 3 in a plan view as viewed in the thickness direction D1 of the rigid section 101. Alternatively, however, the entire radiating electrode 4 may overlap the entire dielectric component 3, or a portion of the radiating electrode 4 may overlap the entire dielectric component 3.

### Second Embodiment

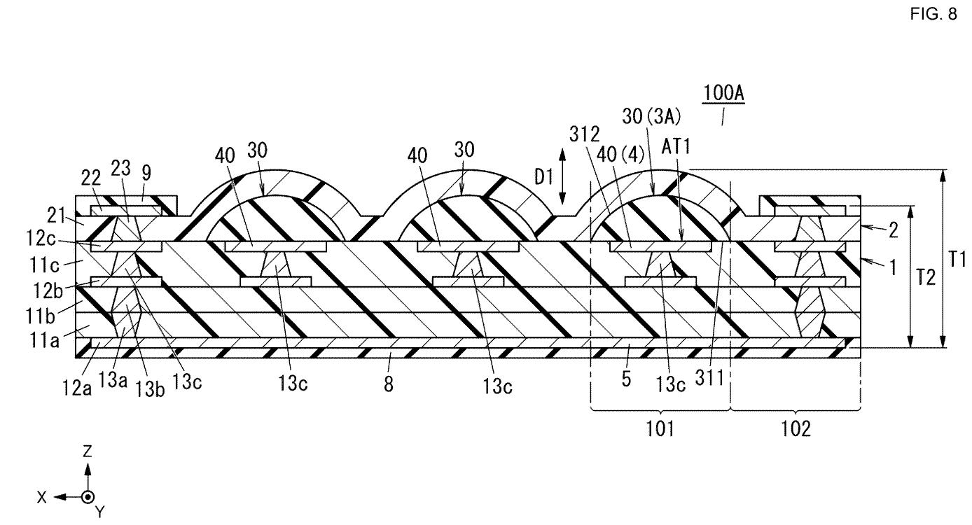

A multilayer substrate module 100A according to a second embodiment will be described with reference to FIGS. 8 to 10. In the multilayer substrate module 100A according to the second embodiment, components similar to those of the multilayer substrate module 100 according to the first embodiment (see FIGS. 1 to 7) are denoted by the same reference signs, and description thereof will be omitted. In FIGS. 8 to 10, as in FIGS. 1 to 7, an orthogonal coordinate system having three axes, an X-axis, a Y-axis, and a Z-axis that are orthogonal to each other, is defined, and the axis along a thickness direction D1 of a rigid section 101 (see FIG. 8) is designated as the Z-axis.

### (1) Structure

The multilayer substrate module 100A according to the second embodiment differs from the multilayer substrate module 100 according to the first embodiment in that the multilayer substrate module 100A includes a dielectric component 3A instead of the dielectric component 3 of the multilayer substrate module 100 according to the first embodiment. In the multilayer substrate module 100A according to the second embodiment, a radiating electrode 4 includes a portion of a first conductive layer 12c and overlaps the dielectric component 3A in the thickness direction D1. In addition, a first conductive layer 12b includes a conductor portion (signal line 7) included in a flexible section 102 and in the rigid section 101.

The dielectric material of the dielectric component 3A includes a ceramic. The ceramic is, for example, an LTCC. The ceramic is not limited to an LTCC and may be, for example, an HTCC. The dielectric material of the dielectric component 3A is not limited to a ceramic, and may be, for example, an FR-4 grade glass epoxy resin. When the dielectric material of the dielectric component 3A is a glass epoxy resin, the dielectric component 3A includes, for example, a glass epoxy resin component equivalent to an FR-4 grade glass epoxy resin substrate.

The dielectric component 3A is a dielectric lens in contact with a second insulating layer 21. More specifically, the dielectric lens has the shape of a plano-convex lens. In the present embodiment, the dielectric component 3A has a first principal surface 311 that is flat and in contact with the radiating electrode 4, and a second principal surface 312 that is curved and in contact with the second insulating layer 21.

The multilayer substrate module 100A according to the second embodiment further includes a plurality of dielectric components 30 disposed between a first multilayer substrate 1 and a second multilayer substrate 2. The dielectric component 3A is one of the dielectric components 30. The dielectric materials of the dielectric components 30 are the same. The relative dielectric constants of the dielectric materials of the dielectric components 30 are the same. The expression “the relative dielectric constants of the dielectric materials of the dielectric components 30 are the same” does not necessarily mean that the relative dielectric constants of the dielectric materials of the dielectric components 30 have precisely the same value. The expression “the relative dielectric constants of the dielectric materials of the dielectric components 30 are the same” includes a case in which, assuming that the relative dielectric constant of the dielectric material of any one of the dielectric components 30 is a reference value, the relative dielectric constants of the dielectric materials of the other dielectric components 30 are 90% or more and 110% or less of the reference value. The Young's moduli of the dielectric materials of the dielectric components 30 are the same. The expression “the Young's moduli of the dielectric materials of the dielectric components 30 are the same” does not necessarily mean that the Young's moduli of the dielectric materials of the dielectric components 30 have precisely the same value. The expression “the Young's moduli of the dielectric materials of the dielectric components 30 are the same” includes a case in which, assuming that the Young's modulus of the dielectric material of any one of the dielectric components 30 is a reference value, the Young's moduli of the dielectric materials of the other dielectric components 30 are 90% or more and 110% or less of the reference value. The shapes of the dielectric components 30 are the same, but may differ from each other.

The rigid section 101 further includes a plurality of radiating electrodes 40 that correspond one-to-one with the dielectric components 30. The radiating electrodes 40 are included in a first conductive layer 12c of the first multilayer substrate 1. The radiating electrode 4 is one of the radiating electrodes 40. The materials of the radiating electrodes 40 are the same. The shapes of the radiating electrodes 40 are the same, but may differ from each other.

The multilayer substrate module 100A according to the present embodiment constitutes a multi-input multi-output (MIMO) radar.

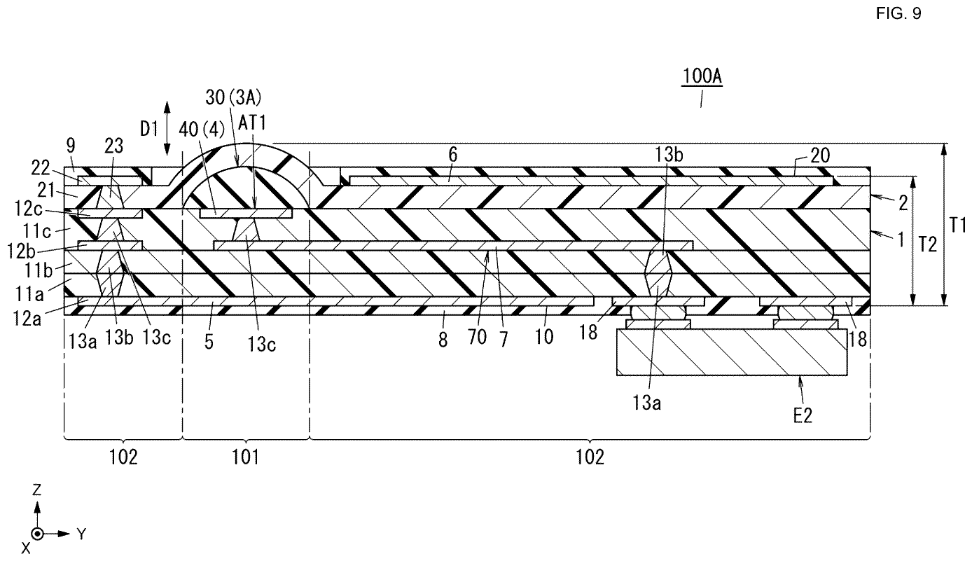

In the present embodiment, as illustrated in FIG. 9, the multilayer substrate module 100A further includes an electronic component E2. The electronic component E2 is disposed on a principal surface 10 of the first multilayer substrate 1 in the flexible section 102 of the multilayer substrate module 100A. The electronic component E2 is, for example, a radar IC chip. The radar IC chip is an IC chip including a signal-processing circuit and other elements for functioning as a millimeter-wave radar together with an antenna AT1 and the signal line 7. The electronic component E2 is connected to the signal line 7 through one of a plurality of land electrodes 18 included in a first conductive layer 12a, one of a plurality of first interlayer connection conductors 13a, and one of a plurality of first interlayer connection conductors 13b.

### (2) Thickness of Multilayer Substrate Module

In the multilayer substrate module 100A, a thickness T1 of the rigid section 101 and a thickness T2 of the flexible section 102 are different. The “thickness T2 of the flexible section 102” is the thickness of a portion of the flexible section 102 in which the second multilayer substrate 2 and the first multilayer substrate 1 are parallel, and is not the thickness of a portion near the boundary between the flexible section 102 and the rigid section 101 around which the thickness varies. In the multilayer substrate module 100A, the thickness T2 of the flexible section 102 is less than the thickness T1 of the rigid section 101.

### (3) Method for Manufacturing Multilayer Substrate Module

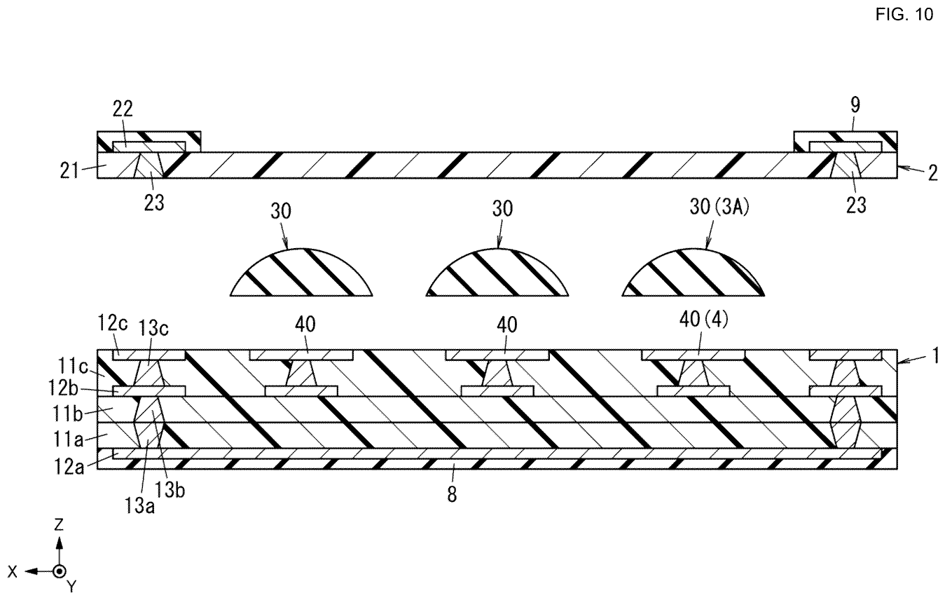

In the method for manufacturing the multilayer substrate module 100A according to the present embodiment, for example, as illustrated in FIG. 10, the first multilayer substrate 1, the dielectric components 30, and the second multilayer substrate 2 are prepared. For example, the first multilayer substrate 1 is placed on a metal plate, and the dielectric components 30 are placed on the first multilayer substrate 1. After that, the second multilayer substrate 2 is placed so as to cover the first multilayer substrate 1 and the dielectric components 30, and pressure is applied from above while heat is applied, thereby causing the first multilayer substrate 1 and the second multilayer substrate 2 to self-bond. Thus, the rigid section 101 and the flexible section 102 are formed. After that, the electronic component E2 is mounted on the flexible section 102 to obtain the multilayer substrate module 100A.

### (4) Effects

Similarly to the multilayer substrate module 100 according to the first embodiment, in the multilayer substrate module 100A according to the second embodiment, the radiating electrode 4 and the ground electrode 5 are included in the rigid section 101, and the thickness T2 of the flexible section 102 is less than the thickness T1 of the rigid section 101. Therefore, the weight of the multilayer substrate module 100A can be reduced without degrading the antenna performance.

In the multilayer substrate module 100A according to the second embodiment, the relative dielectric constant of the dielectric material of the dielectric component 3A is greater than the relative dielectric constant of the second insulating layer 21. Accordingly, in the multilayer substrate module 100A, an abrupt change in the relative dielectric constant between the dielectric lens and air can be reduced, thereby reducing impedance mismatch. In addition, in the multilayer substrate module 100A according to the second embodiment, the radio waves emitted from the radiating electrode 4 can be refracted, making the antenna characteristics uniform regardless of the direction in which the radio waves are emitted.

### Third Embodiment

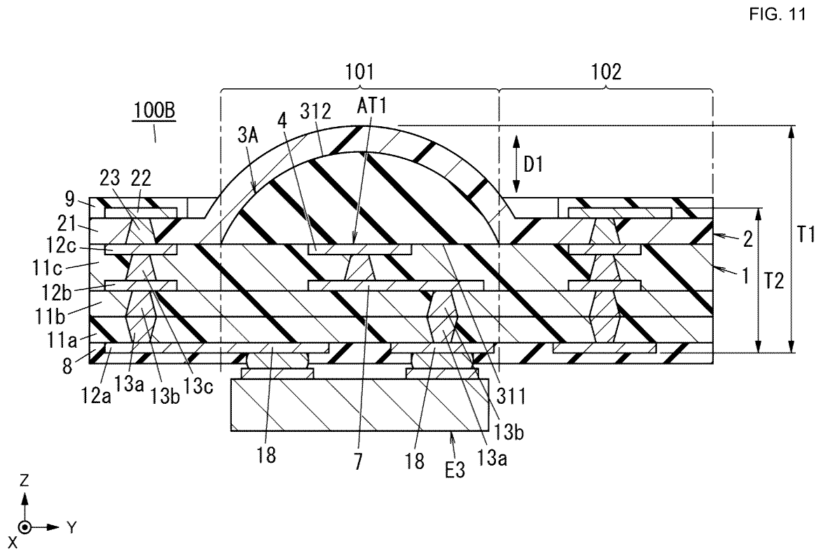

A multilayer substrate module 100B according to a third embodiment will be described with reference to FIG. 11. In the multilayer substrate module 100B according to the third embodiment, components similar to those of the multilayer substrate module 100A according to the second embodiment (see FIGS. 8 to 10) are denoted by the same reference signs, and description thereof will be omitted. In FIG. 11, as in FIGS. 8 to 10, an orthogonal coordinate system having three axes, an X-axis, a Y-axis, and a Z-axis that are orthogonal to each other, is defined, and the axis along a thickness direction D1 of a rigid section 101 is designated as the Z-axis.

### (1) Structure

The multilayer substrate module 100B according to the third embodiment differs from the multilayer substrate module 100A according to the second embodiment in that the multilayer substrate module 100B further includes an electronic component E3 disposed in the rigid section 101.

The electronic component E3 is, for example, a radar IC chip. The electronic component E3 is connected to a signal line 7 through one of a plurality of land electrodes 18 included in a first conductive layer 12a, one of a plurality of first interlayer connection conductors 13a, and one of a plurality of first interlayer connection conductors 13b.

### (2) Effects

Similarly to the multilayer substrate module 100 according to the first embodiment, in the multilayer substrate module 100B according to the third embodiment, the radiating electrode 4 is included in the rigid section 101, and a thickness T2 of a flexible section 102 is less than a thickness T1 of the rigid section 101. Therefore, the weight of the multilayer substrate module 100B can be reduced without degrading the antenna performance.

In addition, in the multilayer substrate module 100B according to the third embodiment, since the electronic component E3 is disposed in the rigid section 101, the mounting reliability of the electronic component E3 can be improved.

### Fourth Embodiment

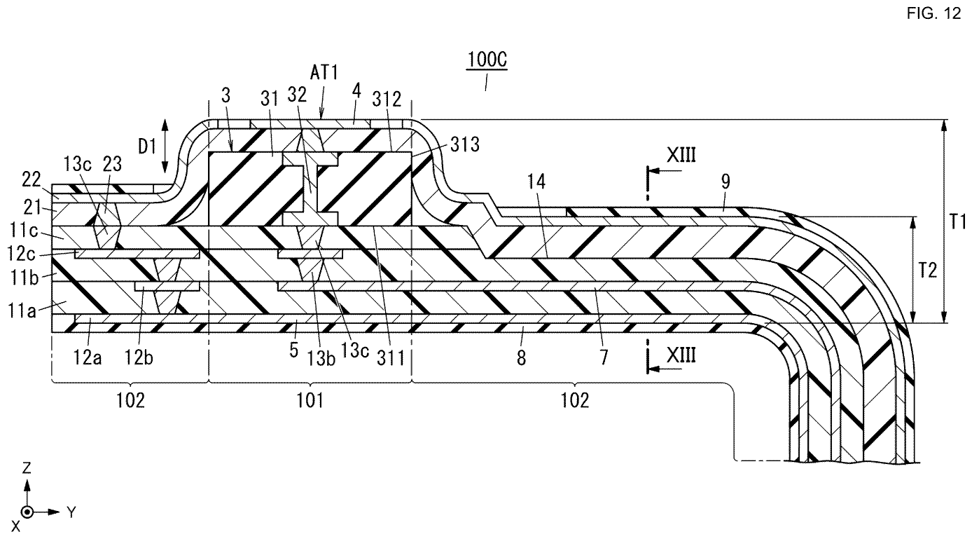

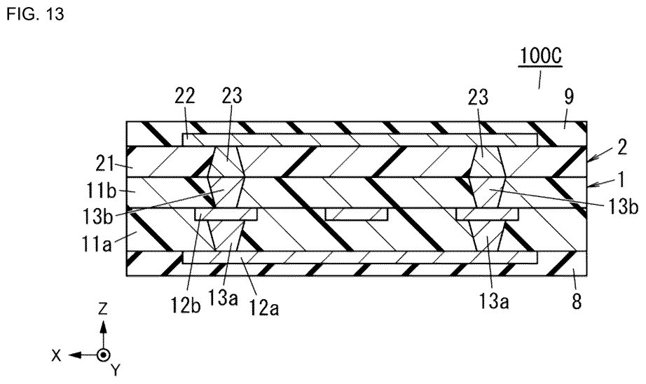

A multilayer substrate module 100C according to a fourth embodiment will be described with reference to FIGS. 12 to 15. In the multilayer substrate module 100C according to the fourth embodiment, components similar to those of the multilayer substrate module 100 according to the first embodiment (see FIGS. 1 to 7) are denoted by the same reference signs, and description thereof will be omitted. In FIGS. 12 to 15, as in FIGS. 1 to 7, an orthogonal coordinate system having three axes, an X-axis, a Y-axis, and a Z-axis that are orthogonal to each other, is defined, and the axis along a thickness direction D1 of a rigid section 101 (see FIG. 12) is designated as the Z-axis.

### (1) Structure

As illustrated in FIG. 12, in the multilayer substrate module 100C according to the fourth embodiment, a flexible section 102 has a cavity 14 formed in a first insulating layer 11c, which is one of a plurality of first insulating layers 11a, 11b, and 11c (three first insulating layers in FIG. 12) that is closest to a second multilayer substrate 2.

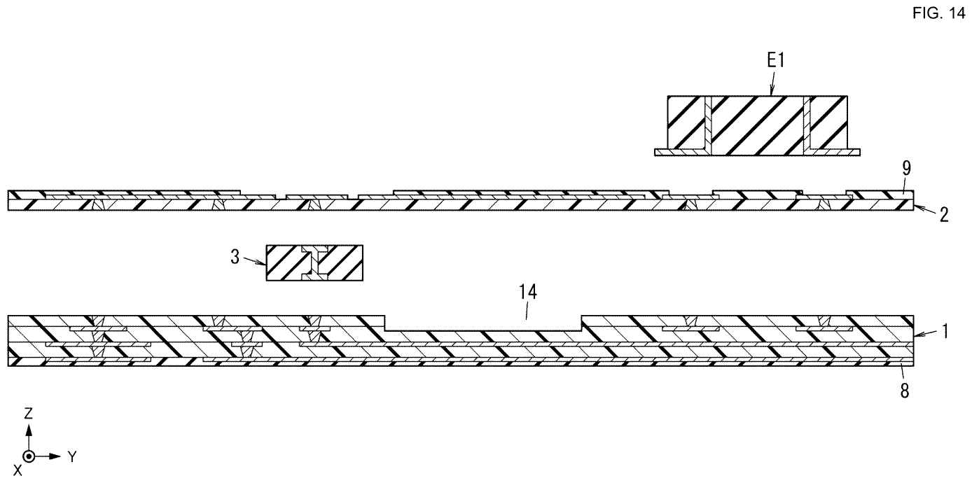

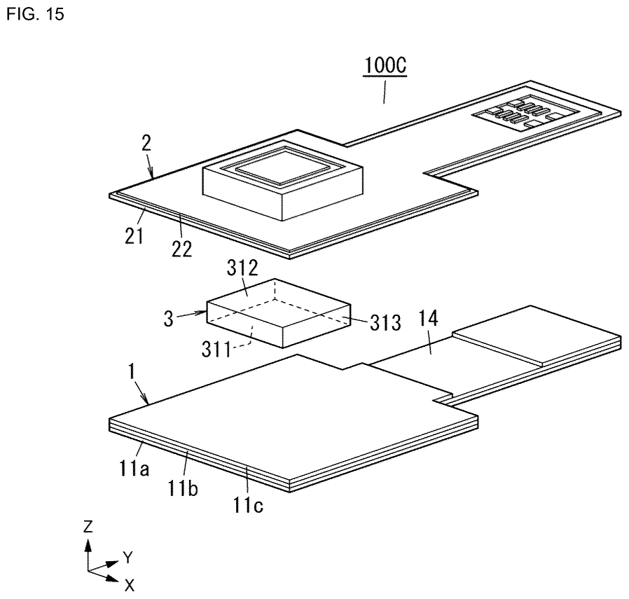

As illustrated in FIGS. 14 and 15, since the first multilayer substrate 1 has the cavity 14 formed in the first insulating layer 11c, the thickness of the first multilayer substrate 1 can be reduced in a region in which the cavity 14 is formed. The cavity 14 is not limited to being formed only in the first insulating layer 11c, and may be formed in both the first insulating layer 11c and the first insulating layer 11b.

In the multilayer substrate module 100C, the cavity 14 is filled with a portion of a second insulating layer 21 of the second multilayer substrate 2.

### (2) Thickness of Multilayer Substrate Module

As illustrated in FIG. 12, in the multilayer substrate module 100C, a thickness T1 of the rigid section 101 and a thickness T2 of the flexible section 102 are different. The “thickness T2 of the flexible section 102” is the thickness of a portion of the flexible section 102 in which the second multilayer substrate 2 and the first multilayer substrate 1 are parallel, and is not the thickness of a portion near the boundary between the flexible section 102 and the rigid section 101 around which the thickness varies. In the multilayer substrate module 100C, the thickness T2 of the flexible section 102 is less than the thickness T1 of the rigid section 101.

### (3) Method for Manufacturing Multilayer Substrate Module

In the method for manufacturing the multilayer substrate module 100C according to the present embodiment, for example, as illustrated in FIGS. 14 and 15, the first multilayer substrate 1, dielectric component 3, and the second multilayer substrate 2 are prepared. For example, the first multilayer substrate 1 is placed on a metal plate, and the dielectric component 3 is placed on the first multilayer substrate 1. After that, the second multilayer substrate 2 is placed so as to cover the first multilayer substrate 1 and the dielectric component 3, and pressure is applied from above while heat is applied, thereby causing the first multilayer substrate 1 and the second multilayer substrate 2 to self-bond. Thus, the rigid section 101 and the flexible section 102 are formed. After that, the flexible section 102 is bent to obtain the multilayer substrate module 100C.

### (4) Effects

Similarly to the multilayer substrate module 100 according to the first embodiment, in the multilayer substrate module 100C according to the fourth embodiment, a radiating electrode 4 and a ground electrode 5 are included in the rigid section 101, and the thickness T2 of the flexible section 102 is less than the thickness T1 of the rigid section 101. Therefore, the weight of the multilayer substrate module 100C can be reduced without degrading the antenna performance.

In addition, in the multilayer substrate module 100C according to the fourth embodiment, since the flexible section 102 has the cavity 14 formed in the first insulating layer 11c, the thickness T2 of the flexible section 102 can be further reduced, thereby making the flexible section 102 more easily bendable.

### Fifth Embodiment

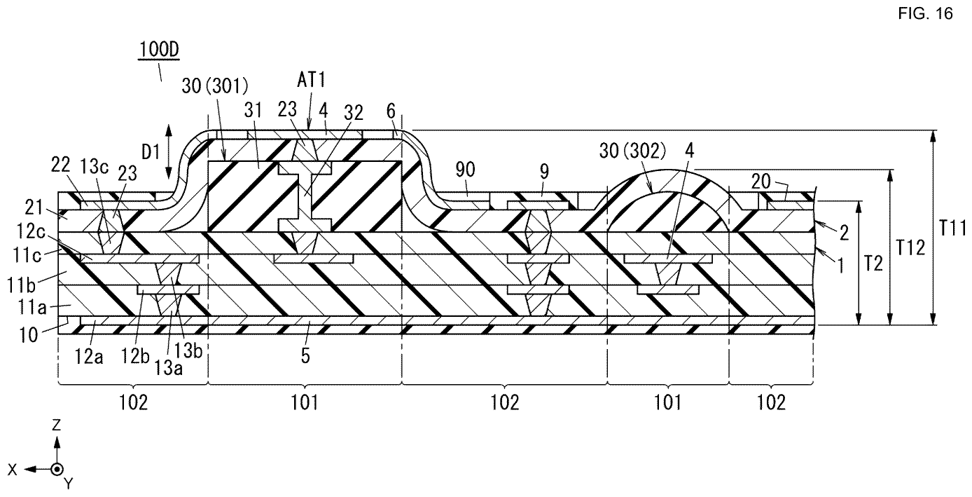

A multilayer substrate module 100D according to a fifth embodiment will be described with reference to FIG. 16. In the multilayer substrate module 100D according to the fifth embodiment, components similar to those of the multilayer substrate module 100 according to the first embodiment (see FIGS. 1 to 7) are denoted by the same reference signs, and description thereof will be omitted.

### (1) Structure

The multilayer substrate module 100D according to the fifth embodiment further includes a plurality of dielectric components 30. The dielectric components 30 include a first dielectric component 301 and a second dielectric component 302 having a shape different from the shape of the first dielectric component 301.

In the multilayer substrate module 100D according to the fifth embodiment, the first dielectric component 301 is the dielectric component 3 (see FIG. 1) of the multilayer substrate module 100 according to the first embodiment, and the second dielectric component 302 is the dielectric component 3A (see FIG. 8) of the multilayer substrate module 100A according to the second embodiment.

### (2) Thickness of Multilayer Substrate Module

In the multilayer substrate module 100D, thicknesses T11 and T12 of a rigid section 101 differ from a thickness T2 of a flexible section 102. The “thickness T2 of the flexible section 102” is the thickness of a portion of the flexible section 102 in which a second multilayer substrate 2 and a first multilayer substrate 1 are parallel, and is not the thickness of a portion near the boundary between the flexible section 102 and the rigid section 101 around which the thickness varies. In the multilayer substrate module 100D, the thickness T2 of the flexible section 102 is less than the thicknesses T11 and T12 of the rigid section 101. The thickness T11 of the rigid section 101 is a thickness of the rigid section 101 in a region including a radiating electrode 4 and the first dielectric component 301. The thickness T12 of the rigid section 101 is a thickness of the rigid section 101 in a region including the second dielectric component 302.

### (3) Effects

Similarly to the multilayer substrate module 100 according to the first embodiment, in the multilayer substrate module 100D according to the fifth embodiment, the radiating electrode 4 and a ground electrode 5 are included in the rigid section 101, and the thickness T2 of the flexible section 102 is less than the thicknesses T11 and T12 of the rigid section 101. Therefore, the weight of the multilayer substrate module 100D can be reduced without degrading the antenna performance.

The first to fifth and other embodiments described above are merely examples of various embodiments of the present disclosure. As long as the weight is reduced, the first to fifth and other embodiments may be modified in various ways in accordance with design, for example, and may be combined as appropriate.

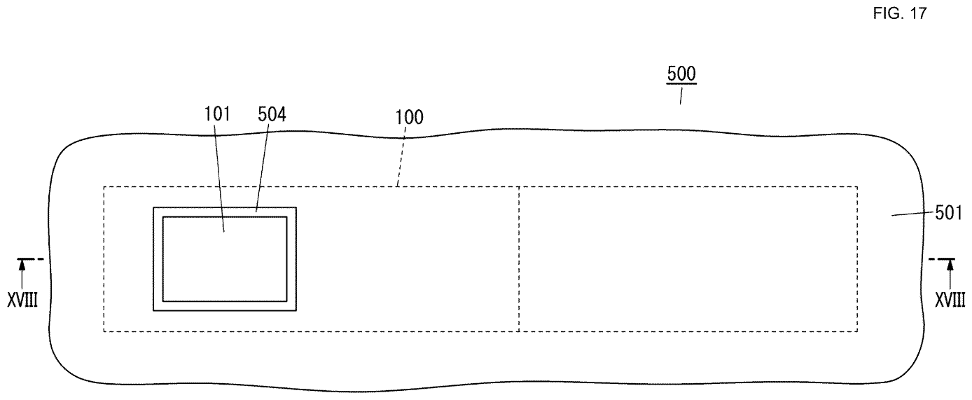

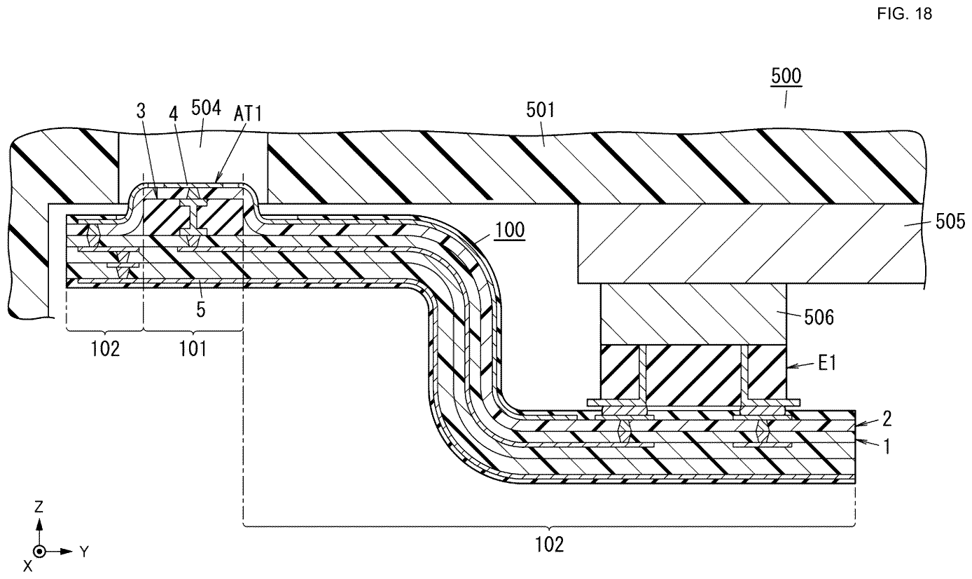

As described above, in the multilayer substrate module 100 according to the first embodiment (see FIG. 7), the size of the antenna AT1 including the radiating electrode 4 and the ground electrode 5 can be reduced. Thus, as illustrated in FIGS. 17 and 18, in the electronic device 500 including the multilayer substrate module 100, a portion of the antenna AT1 can be disposed in an opening 504 in a housing 501 of the electronic device 500 without reducing the rigidity of the housing 501. Accordingly, the electronic device 500 can provide a larger space for arranging other components in the housing 501. In the example illustrated in FIGS. 17 and 18, a cushioning material or the like may be disposed between a portion of the rigid section 101 including the antenna AT1 (portion projecting from the flexible section 102) and an inner peripheral surface of the opening 504 in the housing 501. In the example illustrated in FIGS. 17 and 18, obstacles in the radiation direction of the antenna AT1 can be reduced due to the opening 504 in the housing 501, so that space can be saved without degrading the antenna performance.

The electronic device 500 may be structured such that the housing 501 has a recess instead of the opening 504 for receiving a portion of the rigid section 101 including the antenna AT1 of the multilayer substrate module 100. Also in this case, a larger space for arranging other components can be provided in the housing 501.

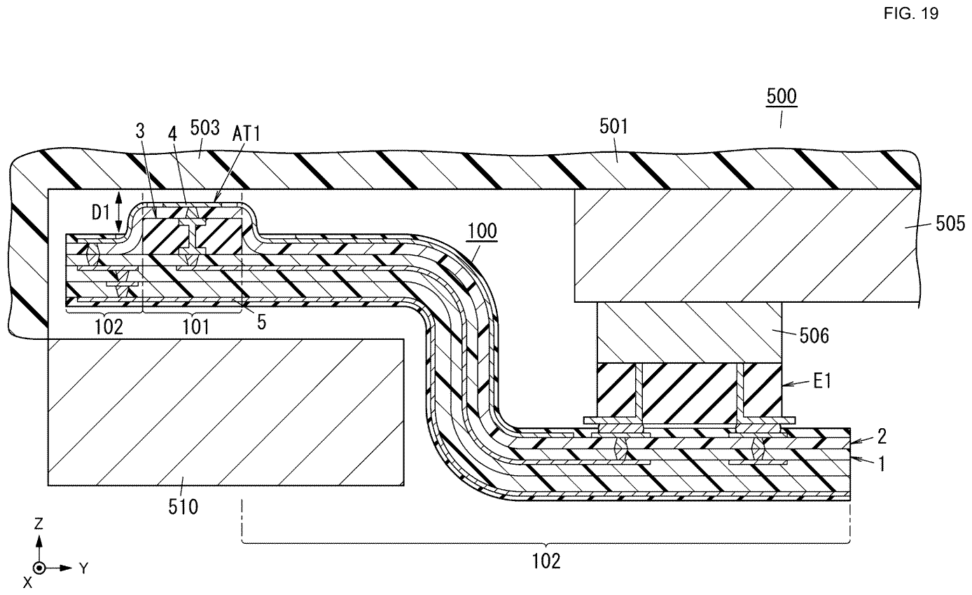

In the electronic device 500, as illustrated in FIG. 19, for example, the multilayer substrate module 100 may be bent in the housing 501 of the electronic device 500 to avoid another component 510 in the housing 501.

### Aspects

The present specification discloses the following aspects.

A multilayer substrate module (100; 100A; 100B; 100C; 100D) according to a first aspect includes a first multilayer substrate (1), a second multilayer substrate (2), and a dielectric component (3; 3A). The first multilayer substrate (1) includes a plurality of first insulating layers (11a, 11b, 11c) and a plurality of first conductive layers (12a, 12b, 12c). The plurality of first insulating layers (11a, 11b, 11c) and the plurality of first conductive layers (12a, 12b, 12c) are laminated. The second multilayer substrate (2) includes a second insulating layer (21) and a second conductive layer (22). The second insulating layer (21) and the second conductive layer (22) are laminated. The dielectric component (3; 3A) is disposed between the first multilayer substrate (1) and the second multilayer substrate (2). In the multilayer substrate module (100; 100A; 100B; 100C; 100D), a section in which the first multilayer substrate (1), the dielectric component (3; 3A), and the second multilayer substrate (2) are laminated is defined as a rigid section (101), and a section in which the first multilayer substrate (1) and the second multilayer substrate (2) are laminated without the dielectric component (3; 3A) interposed therebetween is defined as a flexible section (102). The rigid section (101) includes a radiating electrode (4) and a ground electrode (5). The radiating electrode (4) includes a portion of one conductive layer (second conductive layer 22; first conductive layer 12c) selected from the plurality of first conductive layers (12a, 12b, 12c) and the second conductive layer (22) in a thickness direction (D1) of the rigid section (101). The radiating electrode (4) overlaps the dielectric component (3; 3A) in the thickness direction (D1). The ground electrode (5) includes a portion of one of the plurality of first conductive layers (12a, 12b, 12c) (first conductive layer 12a) and faces the radiating electrode (4) in the thickness direction (D1). At least one selected from the plurality of first conductive layers (12a, 12b, 12c) and the second conductive layer (22) includes a conductor portion included in the flexible section (102) and in the rigid section (101). The flexible section (102) has a thickness (T2) less than a thickness (T1) of the rigid section (101).

According to this aspect, weight can be reduced.

In the multilayer substrate module (100; 100A; 100B; 100C; 100D) according to a second aspect, based on the first aspect, a relative dielectric constant of a dielectric material of the dielectric component (3; 3A) is greater than a relative dielectric constant of a material of each of the plurality of first insulating layers (11a, 11b, 11c), and the relative dielectric constant of the dielectric material of the dielectric component (3; 3A) is also greater than a relative dielectric constant of a material of the second insulating layer (21).

According to this aspect, the antenna performance can be improved.

In the multilayer substrate module (100; 100A; 100B; 100C; 100D) according to a third aspect, based on the first or second aspect, a Young's modulus of a dielectric material of the dielectric component (3; 3A) is greater than a Young's modulus of a material of each of the plurality of first insulating layers (11a, 11b, 11c), and the Young's modulus of the dielectric material of the dielectric component (3; 3A) is also greater than a Young's modulus of a material of the second insulating layer (21).

According to this aspect, an impact applied to the dielectric component (3; 3A) from outside the multilayer substrate module (100; 100A; 100B; 100C; 100D) can be mitigated by the first multilayer substrate (1) and the second multilayer substrate (2). In addition, according to this aspect, the rigidity of the rigid section (101) can be increased, and the bendability of the flexible section (102) can also be increased.

In the multilayer substrate module (100; 100A; 100B; 100C; 100D) according to a fourth aspect, based on any one of the first to third aspects, a material of each of the plurality of first insulating layers (11a, 11b, 11c) and a material of the second insulating layer (21) include the same material.

According to this aspect, warping of the multilayer substrate module (100; 100A; 100B; 100C; 100D) while the multilayer substrate module (100; 100A; 100B; 100C; 100D) is not bent can be reduced.

In the multilayer substrate module (100; 100A; 100B; 100C; 100D) according to a fifth aspect, based on any one of the first to fourth aspects, a material of each of the plurality of first insulating layers (11a, 11b, 11c) and a material of the second insulating layer (21) include a thermoplastic resin.

According to this aspect, the thickness of the multilayer substrate module (100; 100A; 100B; 100C; 100D) can be reduced, and the bendability of the flexible section (102) can be increased.

In the multilayer substrate module (100; 100A; 100B; 100C; 100D) according to a sixth aspect, based on any one of the first to fifth aspects, a dielectric material of the dielectric component (3; 3A) includes a ceramic.

According to this aspect, the rigidity of the rigid section (101) can be increased.

In the multilayer substrate module (100; 100A) according to a seventh aspect, based on any one of the first to sixth aspects, the second conductive layer (22) includes the conductor portion. The conductor portion of the second conductive layer (22) includes a second ground electrode (6) different from a first ground electrode (5) that is the ground electrode (5).

According to this aspect, since the second ground electrode (6) is laminated on the second insulating layer (21) so as to extend over a portion of the second insulating layer (21) included in the rigid section (101) and a portion of the second insulating layer (21) included in the flexible section (102), the noise resistance can be increased.

In the multilayer substrate module (100; 100C; 100D) according to an eighth aspect, based on the seventh aspect, the second ground electrode (6) surrounds the radiating electrode (4) in a plan view of the rigid section (101) as viewed in the thickness direction (D1).

According to this aspect, the noise resistance can be further increased.

In the multilayer substrate module (100; 100A; 100C; 100D) according to a ninth aspect, based on the seventh or eighth aspect, the one first conductive layer (12c; 12b) of the plurality of first conductive layers (12a, 12b, 12c) includes a conductor portion. The conductor portion of the one first conductive layer (12c; 12b) of the plurality of first conductive layers (12a, 12b, 12c) includes a signal line (7). The signal line (7) is included in the rigid section (101) and in the flexible section (102). The first ground electrode (5) is included in the rigid section (101) and in the flexible section (102). The first ground electrode (5) faces the signal line (7). The second ground electrode (6) faces the signal line (7) such that the second insulating layer (21) and the first insulating layer (11c), which is one of the plurality of first insulating layers (11a, 11b, 11c) that is closest to the dielectric component (3; 3A), are disposed between the second ground electrode (6) and the signal line (7).

According to this aspect, the line width of the signal line (7) can be increased, so that the resistance of the signal line (7) can be reduced, thereby reducing loss in the signal line (7).

In the multilayer substrate module (100A; 100B; 100D) according to a tenth aspect, based on any one of the first to ninth aspects, the radiating electrode (4) includes a portion of the first conductive layer (12c), which is one of the plurality of first conductive layers (12a, 12b, 12c) that is closest to the dielectric component (3A). The dielectric component (3A) is a dielectric lens that has a curved surface and that is in contact with the second insulating layer (21).

According to this aspect, the directivity of the radio waves emitted from the radiating electrode (4) can be increased.

In the multilayer substrate module (100; 100A; 100B; 100C; 100D) according to an eleventh aspect, based on any one of the first to tenth aspects, an electronic component (E1; E2) disposed in the flexible section (102) is further included.

According to this aspect, the thickness of the multilayer substrate module (100; 100A; 100B; 100C; 100D) including the electronic component (E1) can be reduced.

In the multilayer substrate module (100B) according to a twelfth aspect, based on any one of the first to eleventh aspects, an electronic component (E3) disposed in the rigid section (101) is further included.

According to this aspect, the mounting reliability of the electronic component (E3) can be improved.

In the multilayer substrate module (100C) according to a thirteenth aspect, based on any one of the first to twelfth aspects, the flexible section (102) has a cavity (14) formed in the first insulating layer (11c), which is one of the plurality of first insulating layers (11a, 11b, 11c) that is closest to the second multilayer substrate (2).

According to this aspect, the flexible section (102) can be more easily bent.

In the multilayer substrate module (100A; 100B) according to a fourteenth aspect, based on any one of the first to thirteenth aspects, a plurality of dielectric components (30) disposed between the first multilayer substrate (1) and the second multilayer substrate (2) are further included. The dielectric component (3) is one of the plurality of dielectric components (30). The rigid section (101) further includes a plurality of radiating electrodes (40) that correspond one-to-one with the plurality of dielectric components (30). The radiating electrode (4) is one of the plurality of radiating electrodes (40).

According to this aspect, the multilayer substrate module can be used as an MIMO radar.

In the multilayer substrate module (100D) according to a fifteenth aspect, based on the fourteenth aspect, the plurality of dielectric components (30) includes a first dielectric component (301) and a second dielectric component (302) having a shape different from a shape of the first dielectric component (301).

In the multilayer substrate module (100; 100A; 100B; 100C; 100D) according to a sixteenth aspect, based on any one of the first to fifteenth aspects, a first cover layer (8) and a second cover layer (9) are further included. The first cover layer (8) covers a principal surface (10) of the first multilayer substrate (1) on a side opposite to a side adjacent to the second multilayer substrate (2). The second cover layer (9) is provided on a principal surface (20) of the second multilayer substrate (2) on a side opposite to a side adjacent to the first multilayer substrate (1). The second cover layer (9) has an opening (90) at which the rigid section (101) is exposed in the thickness direction (D1) of the rigid section (101).

According to this aspect, the reliability can be increased.

An electronic device (500) according to a seventeenth aspect includes the multilayer substrate module (100; 100A; 100B; 100C; 100D) according to any one of the first to sixteenth aspects and a housing (501). The housing (501) accommodates the multilayer substrate module (100; 100A; 100B; 100C; 100D).

According to this aspect, the weight can be reduced.

### REFERENCE SIGNS LIST

1 First Multilayer Substrate
10 principal surface
11a, 11b, 11c first insulating layer
12a, 12b, 12c first conductive layer
13a, 13b, 13c first interlayer connection conductor
14 cavity
2 second multilayer substrate
20 principal surface
21 second insulating layer
22 second conductive layer
23 second interlayer connection conductor
3, 3A dielectric component
30 dielectric component
301 first dielectric component
302 second dielectric component
4 radiating electrode
40 radiating electrode
5 ground electrode (first ground electrode)
6 ground electrode (second ground electrode)
7 signal line
8 first cover layer
9 second cover layer
90 opening
100, 100A, 100B, 100C, 100D multilayer substrate module
101 rigid section
102 flexible section
500 electronic device
501 housing
E1 electronic component
E2 electronic component
E3 electronic component
T1, T11, T12 thickness
T2 thickness

1. A multilayer substrate module comprising:
a first multilayer substrate including a plurality of first insulating layers and a plurality of first conductive layers, the plurality of first insulating layers and the plurality of first conductive layers being laminated;
a second multilayer substrate including a second insulating layer and a second conductive layer, the second insulating layer and the second conductive layer being laminated; and
a dielectric component disposed between the first multilayer substrate and the second multilayer substrate,
wherein a section in which the first multilayer substrate, the dielectric component, and the second multilayer substrate are laminated is defined as a rigid section, and a section in which the first multilayer substrate and the second multilayer substrate are laminated without the dielectric component interposed therebetween is defined as a flexible section,
wherein the rigid section includes
a radiating electrode including a portion of one conductive layer selected from the plurality of first conductive layers and the second conductive layer in a thickness direction of the rigid section, the radiating electrode overlapping the dielectric component in the thickness direction, and
a ground electrode including a portion of one of the plurality of first conductive layers, the ground electrode facing the radiating electrode in the thickness direction, wherein
at least one selected from the plurality of first conductive layers and the second conductive layer includes a conductor portion included in the flexible section and in the rigid section, and
wherein the flexible section has a thickness less than a thickness of the rigid section.

2. The multilayer substrate module according to claim 1, wherein
a relative dielectric constant of a dielectric material of the dielectric component is greater than a relative dielectric constant of a material of each of the plurality of first insulating layers, and
the relative dielectric constant of the dielectric material of the dielectric component is also greater than a relative dielectric constant of a material of the second insulating layer.

3. The multilayer substrate module according to claim 1, wherein
a Young's modulus of a dielectric material of the dielectric component is greater than a Young's modulus of a material of each of the plurality of first insulating layers, and
the Young's modulus of the dielectric material of the dielectric component is also greater than a Young's modulus of a material of the second insulating layer.

4. The multilayer substrate module according to claim 1, wherein
a material of each of the plurality of first insulating layers, and
a material of the second insulating layer include a same material.

5. The multilayer substrate module according to claim 1, wherein
a material of each of the plurality of first insulating layers, and
a material of the second insulating layer include a thermoplastic resin.

6. The multilayer substrate module according to claim 1,
wherein a material of the dielectric component includes a ceramic.

7. The multilayer substrate module according to claim 1, wherein
the second conductive layer includes the conductor portion, and
the conductor portion of the second conductive layer includes a second ground electrode different from a first ground electrode that is the ground electrode.

8. The multilayer substrate module according to claim 7,
wherein the second ground electrode surrounds the radiating electrode in a plan view of the rigid section as viewed in the thickness direction.

9. The multilayer substrate module according to claim 7, wherein
one of the plurality of first conductive layers includes the conductor portion,
the conductor portion of the one of the plurality of first conductive layers includes a signal line included in the rigid section and in the flexible section,
the first ground electrode is included in the rigid section and in the flexible section and faces the signal line, and
the second ground electrode faces the signal line such that the second insulating layer and one of the plurality of first insulating layers that is closest to the dielectric component are disposed between the second ground electrode and the signal line.

10. The multilayer substrate module according to claim 1, wherein
the radiating electrode includes a portion of one of the plurality of first conductive layers that is closest to the dielectric component, and
the dielectric component is a dielectric lens that has a curved surface and that is in contact with the second insulating layer.

11. The multilayer substrate module according to claim 1, further comprising:
an electronic component disposed in the flexible section.

12. The multilayer substrate module according to claim 1, further comprising:
an electronic component disposed in the rigid section.

13. The multilayer substrate module according to claim 1,
wherein the flexible section has a cavity formed in one of the plurality of first insulating layers that is closest to the second multilayer substrate.

14. The multilayer substrate module according to claim 1, further comprising:
a plurality of dielectric components disposed between the first multilayer substrate and the second multilayer substrate, wherein
the dielectric component is one of the plurality of dielectric components,
the rigid section further includes a plurality of radiating electrodes that correspond one-to-one with the plurality of dielectric components, and
the radiating electrode is one of the plurality of radiating electrodes.

15. The multilayer substrate module according to claim 14,
wherein the plurality of dielectric components include
a first dielectric component, and
a second dielectric component having a shape different from a shape of the first dielectric component.

16. The multilayer substrate module according to claim 1, further comprising:
a first cover layer that covers a principal surface of the first multilayer substrate on a side opposite to a side adjacent to the second multilayer substrate; and
a second cover layer provided on a principal surface of the second multilayer substrate on a side opposite to a side adjacent to the first multilayer substrate, and
wherein the second cover layer has an opening at which the rigid section is exposed in the thickness direction of the rigid section.

17. An electronic device comprising:
the multilayer substrate module according to claim 1; and
a housing accommodating the multilayer substrate module.

18. A multilayer substrate module comprising:
a first multilayer substrate; a second multilayer substrate laminated to the first multilayer substrate; and
a dielectric component disposed between the first multilayer substrate and the second multilayer substrate, wherein
a section including the dielectric component defines a rigid section and a section excluding the dielectric component defines a flexible section having a thickness less than the rigid section,
the rigid section includes a radiating electrode disposed on the first multilayer substrate, and
the dielectric component includes a dielectric lens having a flat surface facing the radiating electrode and a curved surface facing the second multilayer substrate.

19. An electronic device comprising:
a housing having a radio-wave transmissive portion; and
a multilayer substrate module accommodated in the housing, wherein
the multilayer substrate module includes a rigid section and a flexible section extending from the rigid section,
the rigid section includes a first multilayer substrate, a second multilayer substrate, and a dielectric component disposed between the first and second multilayer substrates,
the flexible section includes the first and second multilayer substrates laminated directly to each other, and
the rigid section includes a radiating electrode overlapping the dielectric component and aligned with the radio-wave transmissive portion of the housing.

20. The electronic device according to claim 19, wherein the flexible section is bent such that the rigid section projects into the radio-wave transmissive portion.
